(19) United States
(12) Patent Application Publication
(10) Pub. No.: US 2008/0211350 A1
(43) Pub. Date: Sep. 4, 2008

(54) PIEZOELECTRIC RESONATOR ELEMENT AND PIEZOELECTRIC DEVICE

(75) Inventors: Hideo TANAYA, Suwa (JP); Yoshiyuki YAMADA, Minowa (JP); Yukihiro TONEGAWA, Minowa (JP); Katsumi KURODA, Minowa (JP)

Correspondence Address: HARNESS, DICKEY & PIERCE, P.L.C., P.O. BOX 828, BLOOMFIELD HILLS, MI, 48303, US

(73) Assignee: EPSON TOYOCOM CORPORATION, Tokyo (JP)

(21) Appl. No.: 11/840,339

(22) Filed: Aug. 17, 2007

(30) Foreign Application Priority Data
Aug. 18, 2006 (JP) 2006-223318
Aug. 18, 2006 (JP) 2006-223319
Aug. 18, 2006 (JP) 2006-223320
Aug. 17, 2007 (JP) 2007-212634

(51) Int. Cl. H03H 9/205; H01L 41/047; H01L 41/053

(52) U.S. Cl. 310/328; 310/364; 310/344

(57) ABSTRACT

A piezoelectric resonator element includes: a base in a predetermined length, the base being made of a piezoelectric material; a plurality of resonating arms extending from a first end of the base; a joining part connected to a second end apart from the first end of the base by a predetermined distance; a connecting part connected to the joining part and extending in a width direction of the piezoelectric resonator element; a supporting arm connected to the connecting part and extending in a same direction as the resonating arm at an outer side of the plurality of resonating arms. A ratio L3/h is 40% or less where h is a length dimension from the first end of the base to the second end opposite to the resonating arms of the piezoelectric resonator element, and L3 is a width dimension of the connecting part connecting the supporting arm to the base through the joining part.

### BACKGROUND

1. Technical Field

The present invention relates to improvement on a piezoelectric resonator element and a piezoelectric device including the piezoelectric resonator element in its package or case.

2. Related Art

Piezoelectric devices, including a piezoelectric resonator, a piezoelectric oscillator and the like, have been widely used for small-sized information equipment, such as hard disc drives (HDDs), mobile computers, and IC cards, and for mobile communications equipment such as cellular phones, car-phones, and paging systems, and piezoelectric gyro sensors, etc.

FIG. 14 is a schematic plan view illustrating an example of a piezoelectric resonator element conventionally used in the piezoelectric devices.

In the figure, a piezoelectric resonator element 1, whose shape shown in the figure is formed by etching a piezoelectric material such as quartz or the like, is provided with a base 2 having a rectangular shape, which is mounted to a package (not shown) or the like, and a pair of resonating arms 3 and 4, which extends from the base 2 in the vertical direction as viewed in the figure. Long grooves 3a and 4a are formed on the main surfaces (front and back surface) of resonating arms, and necessary driving electrodes are formed. Refer to JP-A-2002-261575.

In the piezoelectric resonator element 1 as above, when a driving voltage is applied via driving electrodes, the resonating arms 3 and 4 perform a flexural vibration so that their distal parts are moved closer and then apart, resulting in a signal having a given frequency being taken out.

Here, the piezoelectric resonator element 1, in which lead-out electrodes are formed at the positions indicated as numerals 5 and 6 on the base 2, is fixed to a base body such as a package or the like with adhesives 7 and 8 applied on the lead-out electrodes.

After fixing and supporting with the adhesive, cut parts 9 are formed to the base 2 so that the flexural vibration of the resonating arms is prevented from being hindered by a remaining stress caused by the differences in the linear expansion coefficient between the material of the package or the like, and the material of the piezoelectric resonator element.

Each part of the piezoelectric resonator element 1 is downsized, so that the length of the base is accordingly shortened, miniaturizing the piezoelectric resonator element 1.

However, the piezoelectric resonator element 1, which is miniaturized as such, may not provide a favorable result in its temperature characteristic test due to the following reasons.

That is, when the piezoelectric resonator element 1 is made of quartz crystal, the linear expansion coefficient is 13.8 ppm/° C. However, a package accommodating it and being bonded therewith is an alumina ceramic package whose linear expansion coefficient is 7.0 ppm/° C.

Further, in a bonding step (mounting step) of the piezoelectric resonator element 1 to the package, a conductive adhesive is used and cured at about 200° C. When the conductive adhesive is back to room temperature after curing, stress corresponding to difference of respective linear expansion coefficients between the piezoelectric resonator element 1 and the package acts on a bonding portion.

Therefore, when a temperature characteristic test is performed, for example, as shown in FIG. 15, an actual characteristic is shown as a line B while an ideal temperature characteristic is shown as a line A.

That is, when the characteristic is tested by changing a temperature environment from −50° C. to 100° C., a frequency is shifted toward to a plus at −50° C. due to stress acting on the bonding portion mentioned above. Further, when the piezoelectric resonator element 1 is left at −55° C. for 1000 hours (H) (in a case of a piezoelectric resonator of 32 kHz), the frequency is shifted toward a minus because it cannot completely recover from the stress condition since it is gone back to room temperature after the largest stress at −55° C. acted.

While an average temperature characteristic is shown in FIG. 15, a result from the temperature characteristic test on each sample is plotted in FIG. 16. As indicated as letter P in FIG. 16, compared to an ideal frequency and temperature characteristic, some samples show high frequency in a low temperature region.

By the way, a state being different from an ideal frequency-temperature characteristic is called frequency distortion. As shown in FIG. 16, frequency distortion in the low temperature region is considered to mainly occur due to two causes.

One of them is an effect in which an arm width 1 of a resonating arm is further downsized as it is from 40 μm to 60 μm.

Another of them, when a driving electrode formed on each resonating arm, which is not shown, is formed by depositing gold on a lower layer made of chromium, the chromium layer as the lower layer is likely to cause frequency distortion at a low temperature. This seems to be caused by film stress generated by difference of a linear expansion coefficient between Young's modulus that goes up at a low temperature as shown in FIG. 17 and a piezoelectric material of the resonator element affecting on the resonator element. Further, this film stress hinders a flexural vibration, causing an elevation of a value of crystal impedance (CI).

When a film thickness of the chromium layer as above is too thin, an effect sufficiently to bond gold is not expected. However, if it is too thick, an affect of the stress mentioned above becomes larger.

On the other hand, when a thickness of the gold layer formed on the chromium layer is too thick, frequency distortion at a low temperature is caused although it is not as much as a case of the chromium layer. Further, when the thickness of the gold layer formed on the chromium layer is too thin, chromium is diffused and oxidized on a surface of the gold layer by an effect of heat in a later step, increasing conduction resistance.

It is hard to determine a film thickness of an electrode film that can solve such various problems.

### SUMMARY

An advantage of the invention is to provide a piezoelectric resonator element and a piezoelectric device that have a favorable temperature characteristic while downsizing thereof is achieved.

A piezoelectric resonator element according to a first aspect of the invention includes: a base in a predetermined length, the base being made of a piezoelectric material; a plurality of resonating arms extending from a first end of the base; a joining part connected to a second end apart from the first end of the base by a predetermined distance; a connecting part connected to the joining part and extending in a width direction of the piezoelectric resonator element; a supporting arm connected to the connecting part and extending in a same direction as the plurality of resonating arms at an outer side of the resonating arms. Further, a ratio L3/h is 40% or less where h is a length dimension from the first end of the base to the second end opposite to the resonating arms of the piezoelectric resonator element, and L3 is a width dimension of the connecting part connecting the supporting arm to the base through the joining part.

According to the structure as above, the resonating arms that perform a flexural vibration extend from the first end of the base, while the supporting arm extends from the second end of the base having the predetermined length.

Because of the structure, in a case where the supporting arm is bonded to a base substrate such as a package by adhesive bonding or the like, a stress change, which is produced at the bonding portion due to a change of surrounding temperature or a drop shock or the like, is seldom affected to the resonating arms from the bonding portion of the supporting arm through the second end of the base, and further, through the distance of the predetermined length of the base. As a result, the temperature characteristic particularly shows well.

Also, in contrast, vibration leakage from the resonating arms that perform the flexural vibration is hardly propagated, since the vibration leakage is reached to the supporting arm spaced apart from the base through the predetermined length of the base. Namely, if the length of the base is extremely short, it can be considered that a situation that is hard to control occurs since a leaked component of the flexural vibration spreads over the supporting arms. However, in the invention, such situation is thoroughly avoided.

In addition to the advantageous effects as above, since the supporting arms are extended from the second end of the base in the width direction, and extended in the same direction of the resonating arms at outer side of the resonating arms, the whole size can be made compact.

Further, in the piezoelectric resonator element according to the first aspect of the invention, the ratio L3/h is 40% or less where h is the length dimension from the first end of the base to the second end opposite to the resonating arms of the piezoelectric resonator element and L3 is the width dimension of the connecting part connecting the supporting arm to the base through the joining part.

Accordingly, in the structure from each of the resonating arms serving as an excitation part to the supporting arm serving as a bonding portion, a part where stress is adequately concentrated is provided other than on the supporting arm itself directly bonded to the package, the resonating arms highly affected by excitation, and a portion on the base end provided with the resonating arms described above. The part can prevent the effect by the stress from the supporting arm from being propagated to the resonating arms. Consequently, the piezoelectric resonator element having a favorable temperature characteristic is provided while being down sized. When the ratio exceeds 40%, it is found that the temperature characteristic extremely deteriorates.

Further, in this case, the ratio L3/h is preferably from 20% to 40% inclusive where h is the length dimension from the first end of the base to the second end opposite to the resonating arms of the piezoelectric resonator element and L3 is the width dimension of the connecting part. According to the structure above, when the ratio L3/h does not reach 20% or more, a problem in which the piezoelectric resonator element is broken in an assembly step due to lack of sufficient rigidity arises.

A piezoelectric resonator element according to a second aspect of the invention includes: a base in a predetermined length, the base being made of a piezoelectric material; a plurality of resonating arms extending from a first end of the base; a joining part connected to a second end apart from the first end of the base by a predetermined distance; a connecting part connected to the joining part and extending in a width direction of the piezoelectric resonator element; a supporting arm connected to the connecting part and extending in a same direction as the plurality of resonating arms at an outer side of the resonating arms. Further a ratio r/e is 40% or less where r is a width of the joining part and e is a width of the base.

According to the structure above, since the ratio r/e is 40% or less where r is the width dimension of the joining part and e is the width dimension of the base, each of the resonating arms serving as the excitation part is extremely hard to receive an effect from the supporting arm serving as the bonding portion.

Further, in this case, the ratio r/e is preferably from 23% to 40% inclusive where r is the width of the joining part and e is the width of the base.

As above, when the ratio r/e is less than 23%, it is found that the joining part may be split by an impact from outside such as a drop shock.

Therefore, by making the ratio r/e from 23% to 40% where r is the width dimension of the joining part and e is the width dimension of the base, the piezoelectric resonator element in which each of the resonating arms serving as the excitation part is extremely hard to receive an effect from the supporting arm including the bonding portion to the package while not easily damaged by an impact from outside is provided.

A piezoelectric resonator element according to a third aspect of the invention includes a base in a predetermined length, the base being made of a piezoelectric material; a plurality of resonating arms extending from a first end of the base, the plurality of resonating arms including an excitation electrode serving as a driving electrode to which a driving voltage is applied formed thereon. The excitation electrode includes a chromium layer serving as a lower layer and having a thickness of 300 \acute{Å} or less and a gold layer serving as an electrode layer and having a thickness of 500 \acute{Å} or less.

According to the structure above, the excitation electrode is formed on the resonating arms extended from the base. Therefore a distal part of each of the resonating arms performs a flexural vibration so as to move closer and then apart by application of a driving voltage. To perform such a flexural vibration, the driving voltage is propagated to the resonating arms while the excitation electrode forming an adequate electric field inside includes the chromium layer as the lower layer and the gold layer as the electrode layer formed thereon. The film thickness of the chromium layer of the electrode film is 300 \acute{Å} or less and the thickness of the gold layer is 500 \acute{Å} or less. Here, the chromium layer having the thickness of 300 \acute{Å} or less can prevent film stress of the electrode parts at a low temperature from being too large. Further, when the thickness of the gold layer is 500 \acute{Å} or less, the film stress of the electrode parts does not become too large. As a result, difference with respect to an ideal frequency-temperature characteristic generated at the low temperature, namely, frequency distortion, can be prevented. Accordingly, even when the piezoelectric resonator element is made small, a piezoelectric resonator element having a favorable temperature characteristic can be provided by suppressing the CI value hindering a flexural vibration when a temperature is low and preventing frequency distortion at the low temperature while serving sufficient conduction performance.

In this case, the piezoelectric resonator element may further include a joining part connected to a second end apart from the first end of the base by a predetermined distance, a connecting part connected to the joining part and extending in a width direction of the piezoelectric resonator element, and a supporting arm connected to the connecting part and extending in a same direction as the plurality of resonating arms at an outer side of the resonating arms.

Further, the piezoelectric resonator element according to the first aspect of the invention, the connecting part may include a reduced-width portion in which a width of the connecting part is constricted, and a width dimension L3 of the connecting part may be a width dimension of the reduced-width portion.

According to the structure above, a structure partially having a low rigidity formed in order to prevent the effect of the stress from the supporting arm from propagating to the resonating arms can be appropriately arranged.

A piezoelectric device according to a fourth aspect of the invention includes a piezoelectric resonator element and a package housing the piezoelectric resonator element. The piezoelectric resonator element includes a base in a predetermined length, the base being made of a piezoelectric material; a plurality of resonating arms extending from a first end of the base, a joining part connected to a second end apart from the first end of the base by a predetermined distance; a connecting part connected to the joining part and extending in a width direction of the piezoelectric resonator element; a supporting arm connected to the connecting part and extending in a same direction as the plurality of resonating arms at an outer side of the resonating arms. Further, a ratio L3/h is 40% or less where h is a length dimension from the first end of the base to the second end opposite to the resonating arms of the piezoelectric resonator element and L3 is a width dimension of the connecting part connecting the supporting arm to the base through the joining part.

According to the structure above, in the piezoelectric resonator element to be housed in the package, the ratio L3/h is 40% or less where h is the length dimension from the first end of the base to the second end opposite to the resonating arms of the piezoelectric resonator element and L3 is the width dimension of the connecting part connecting the supporting arm to the base through the joining part.

Therefore, an effect same as that of the first aspect of the invention is obtained. Particularly, a part where stress is adequately concentrated is provided other than on the supporting arm itself directly bonded to the package, the resonating arms highly affected by excitation, and a portion on the base end provided with the resonating arms described above. The part can prevent the effect by the stress from the supporting arm from being propagated to the resonating arms. Consequently, the piezoelectric device having a favorable temperature characteristic is provided while being down sized.

A piezoelectric device according to a fifth aspect of the invention includes a piezoelectric resonator element and a package housing the piezoelectric resonator element. The piezoelectric resonator element includes a base in a predetermined length, the base being made of a piezoelectric material; a plurality of resonating arms extending from a first end of the base, a joining part connected to a second end apart from the first end of the base by a predetermined distance; a connecting part connected to the joining part and extending in a width direction of the piezoelectric resonator element; a supporting arm connected to the connecting part and extending in a same direction as the plurality of resonating arms at an outer side of the resonating arms. Further, a ratio r/e is 40% or less where r is a width of the joining part and e is a width of the base.

According to the structure above, in the piezoelectric resonator element to be housed in the package, since the ratio r/e is 40% or less where r is the width of the joining part and e is the width of the base, each of the resonating arms serving as an excitation part is extremely hard to receive an effect from the supporting arm serving as a bonding portion. Therefore, the piezoelectric device having a favorable temperature characteristic is provided while being down sized.

A piezoelectric device according to a sixth aspect of the invention includes a piezoelectric resonator element and a package housing the piezoelectric resonator element. The piezoelectric resonator element includes a base in a predetermined length, the base being made of a piezoelectric material; a plurality of resonating arms extending from a first end of the base, the plurality of resonating arms including an excitation electrode serving as a driving electrode to which a driving voltage is applied formed thereon. The excitation electrode includes a chromium layer serving as a lower layer and having a thickness of 300 \acute{Å} or less, and a gold layer serving as an electrode layer and having a thickness of 500 \acute{Å} or less.

In this case, the package may include a body made of ceramics in a box shape, the body having a through hole communicated with outside and to be sealed; a lid made of a metal; and a brazing material made of a gold-germanium alloy for sealing the lid and the body. According to the structure as above, by using the brazing material made of the gold-germanium alloy, bonding strength is sufficiently obtained even a size of a bonding allowance is limited compared to a case where a lid made of glass is bonded with a brazing material that is a low-melting glass. Particularly, in degassing using a sealing hole, excellent airtightness can be achieved without affecting bonding of the lid even when heat is applied thoroughly. Further, when passing through a reflow oven in a mounting step, the brazing material is not re-melted, providing excellent bonding performance.

### BRIEF DESCRIPTION OF THE DRAWINGS

The invention will be described with reference to the accompanying drawings, wherein like numbers reference like elements.

FIG. 1 is a schematic plan view showing a piezoelectric device according to one embodiment of the invention.

FIG. 2 is a sectional view taken along a line A-A in FIG. 1.

FIG. 3 is a schematic enlarged plan view of a piezoelectric resonator element according to the embodiment shown in FIG. 1.

FIG. 4 is a sectional view taken along a line B-B on a resonating arm in FIG. 1.

FIG. 5 is a circuit diagram illustrating an example of an oscillation circuit using the piezoelectric resonator element in FIG. 1.

FIG. 6 is a graph showing a dimension of the piezoelectric resonator element shown in FIG. 3 and a frequency shift (difference) with respect to an ideal temperature characteristic.

FIG. 7 is a graph showing the dimension of the piezoelectric resonator element shown in FIG. 3 and variation of frequency of the temperature characteristic.

FIG. 8 is a graph showing the dimension of the piezoelectric resonator element shown in FIG. 3 and a frequency shift of the temperature characteristic.

FIG. 9 is a graph showing a result of a temperature characteristic test of the piezoelectric device (piezoelectric resonator element) in FIG. 1.

FIG. 10 is a table showing a relation between each thickness of a chromium film and a gold film composing an electrode film of an excitation electrode and a frequency characteristic at a low temperature.

FIG. 11 is a partial sectional view showing one example of a bonding structure of a lid of the piezoelectric device in FIG. 1.

FIG. 12 is a flow chart showing one example of a method for manufacturing the piezoelectric device according to the invention.

FIG. 13 is a diagram showing coordinate axes of a quartz Z plate.

FIG. 14 is a schematic plan view of a conventional piezoelectric resonator element.

FIG. 15 is a diagram showing a temperature characteristic of the piezoelectric resonator element shown in FIG. 14.

FIG. 16 is a graph showing a result of a temperature characteristic test of a small-sized piezoelectric device in a conventional type.

FIG. 17 is a graph showing a relation between Young's modulus and a temperature of a lower layer of an electrode.

### DESCRIPTION OF EXEMPLARY EMBODIMENTS

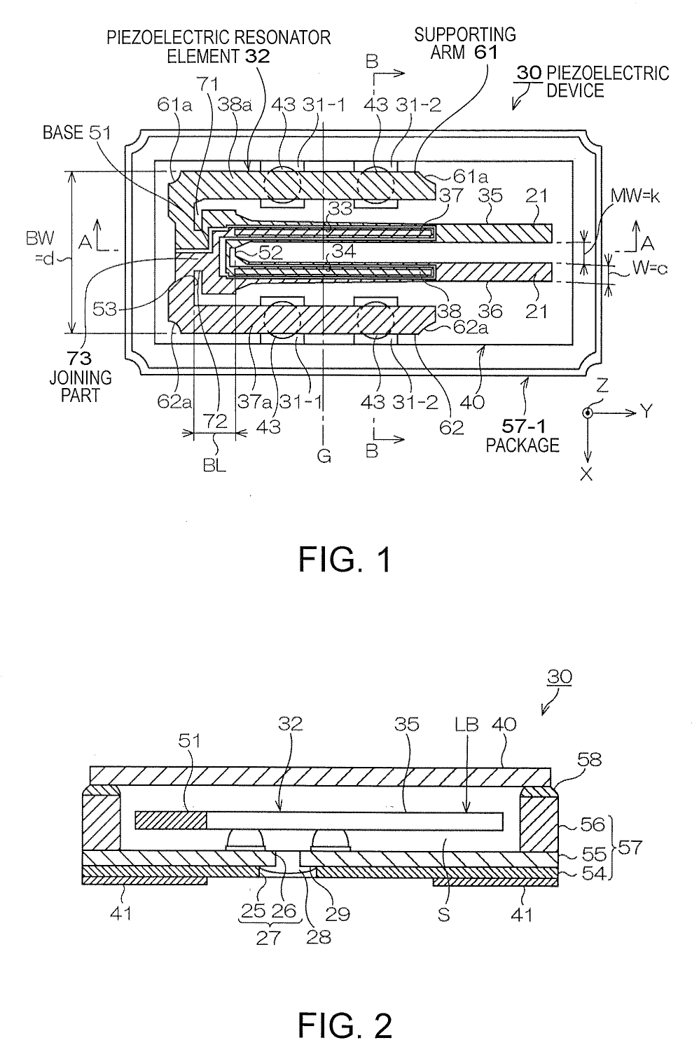

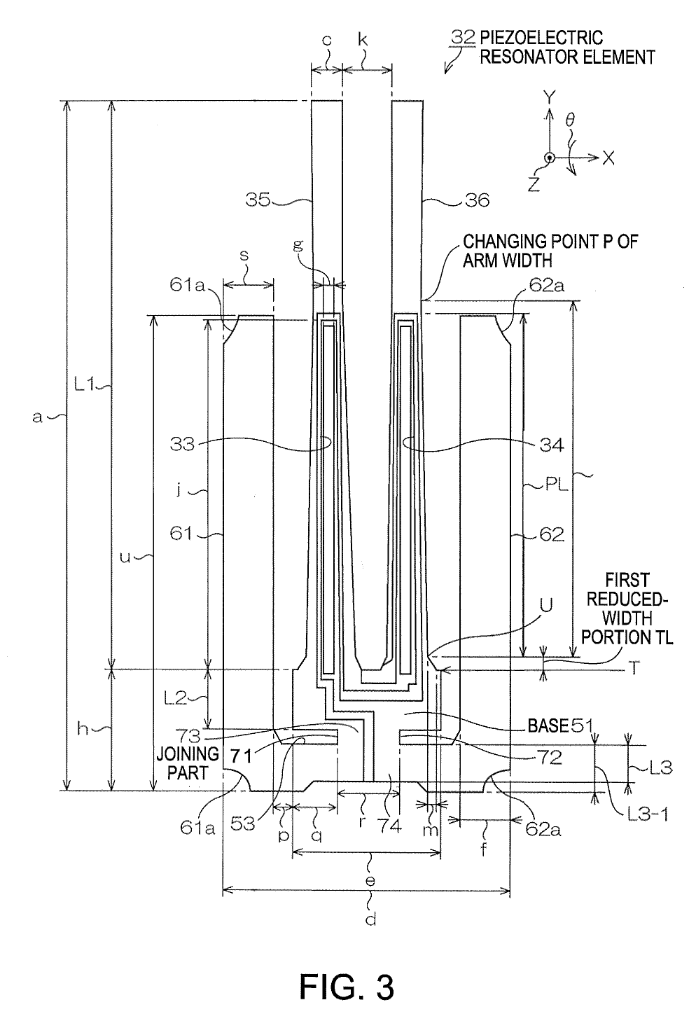

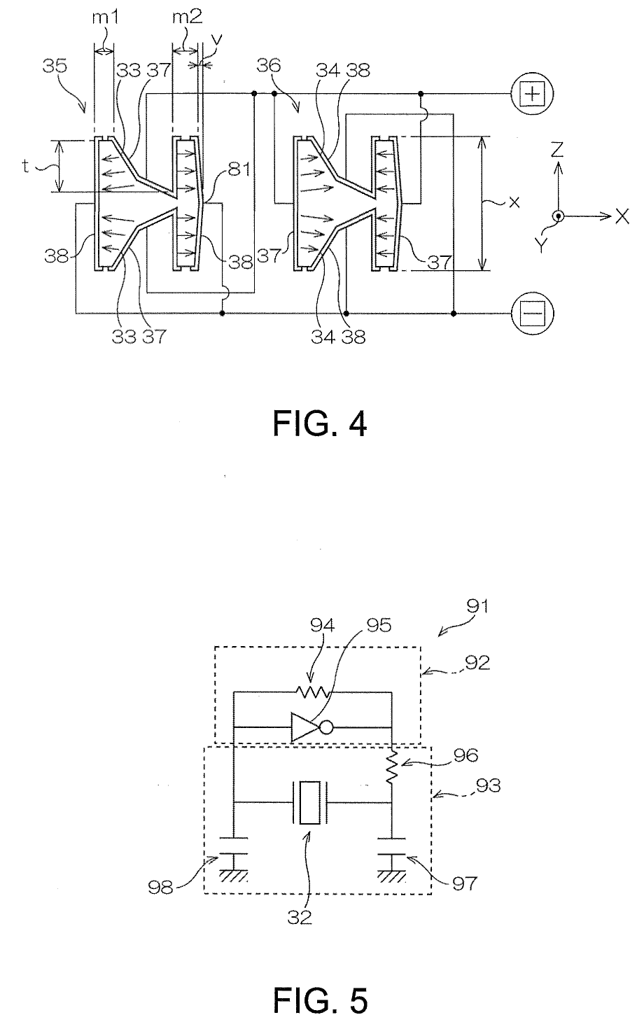

FIGS. 1 and 2 show a piezoelectric device according to an embodiment of the invention. FIG. 1 is a schematic plan view thereof, and FIG. 2 is a schematic sectional-view taken along a line A-A in FIG. 1. In addition, FIG. 3 is an enlarged plan view to explain details of a piezoelectric resonator element 32 in FIG. 1. FIG. 4 is a sectional view taken along a line B-B on resonating arms in FIG. 1.

Referring to the drawings, a piezoelectric device 30 is an example including a piezoelectric resonator. The piezoelectric device 30 houses the piezoelectric resonator element 32 in a package 57 serving as a base body.

As shown in FIGS. 1 and 2, the package 57 is formed in a rectangular box shape, for example, by laminating a first substrate 54, a second substrate 55, and a third substrate 56. For example, it is formed as follows: a ceramic green sheet made of aluminum oxide is formed as an insulation material; the sheet is formed in a shape as shown in the figures; and then fired.

The package 57 is hermetically sealed by bonding a lid 40, which is made of glass and transparent, with a sealing member 58 after housing the piezoelectric resonator element 32. As a result, frequency can be adjusted by trimming the electrode, or the like of the piezoelectric resonator element 32 with an irradiation of laser light from an outside after sealing the lid 40.

When frequency adjustment after sealing the lid is not required, a metal lid can be used as the lid 40. For example, using a lid made of Kovar allows a lid sealing by seam welding as it will be described later.

The package 57 has a through hole 27 on its bottom for degassing during manufacturing steps. The through hole 27 is provided with a first hole 25 formed in the first substrate 54, and a second hole 26 formed in the second substrate 55. The second hole 26 has an outer diameter smaller than that of the first hole 25, and communicates with the first hole 25.

Further, the through hole 27 is sealed by filling a sealing member 28 so as to make the inside of the package 57 in an airtight condition.

The package 57 includes an inner space S formed by removing a material inside of the third substrate 56 as shown in FIG. 2. The inner space S is a space for housing the piezoelectric resonator element 32.

The piezoelectric resonator element 32 is placed and bonded onto electrode parts 31-1 and 31-2 formed on the substrate 55 serving as the second substrate of the package 57 with conductive adhesives 43 at positions of supporting arms 61 and 62 of the piezoelectric resonator element 32 to be described later. On the positions, a lead-out electrode, which will be described later, is formed.

Therefore, the bonding strength for bonding the piezoelectric resonator element 32 is superior to that of the piezoelectric device 30 in FIG. 1.

The piezoelectric resonator element 32 is made of quartz crystal, for example. Other than quartz crystal, lithium tantalate, lithium niobate or other piezoelectric materials can be used. The piezoelectric resonator element 32 includes abase 51, and a pair of resonating arms 35 and 36 as shown in FIG. 1. The resonating arms 35 and 36 extend toward the right direction in parallel with each other from one end (the left end in the figure) of the base 51.

On the front and back sides of the main surface of the resonating arms 35 and 36, long grooves 33 and 34 that extend in the longitudinal direction are preferably formed respectively. As shown in FIGS. 1 and 2, the long grooves 33 and 34 are provided with excitation electrodes 37 and 38 that serve as driving electrodes therein.

In the embodiment, a distal part of each of the resonating arms 35 and 36 is gradually widened in width as slightly tapered so as to increase in weight, serving as a plummet. As a result, the resonating arms can easily perform a flexural vibration.

In addition, the piezoelectric resonator element 32 is widened in the width direction of the base 51 at the other end (the left end as viewed in the figure) across the given distance BL (the length L2 of the base and a cut part) with respect to the one end provided with the resonating arms. The piezoelectric resonator element 32 is also provided with the supporting arms 61 and 62 at the positions outer side of both of the resonating arms 35 and 36. The supporting arms 61 and 62 extend in the direction in which each of the resonating arms 35 and 36 extends (in the right direction in FIG. 1) in parallel with the resonating arms 35 and 36.

The outer shape of the piezoelectric resonator element 32 having a tuning-fork-like shape and the long groove disposed in each of the resonating arms can be precisely formed, for example, by wet etching a material such as a quartz wafer or the like with a hydrofluoric solution or dry etching it.

The excitation electrodes 37 and 38 are provided in the long grooves 33 and 34, and to the side surface of each of the resonating arms. In each of the resonating arms, the electrode in the long groove and the electrode provided to the side surface have opposite polarity. The excitation electrodes 37 and 38 are respectively extended to the supporting arms 61 and 62 as lead-out electrodes 37a and 38a. Accordingly, in a case where the piezoelectric device 30 is mounted on a mounting substrate or the like, a driving voltage from outside is applied to each of the lead-out electrodes 37a and 38a in each of supporting arms 61 and 62 of the piezoelectric resonator element 32 via each of the electrode parts 31-1 and 31-2 from a mounting terminal 41 so as to reach the excitation electrodes 37 and 38.

Then electric field efficiency inside of a region including the long groove of the resonating arm can be increased with the driving voltage applied to the excitation electrode in the long grooves 33 and 34, at the time of being driven.

The excitation electrodes 37 and 38 are formed of an electrode layer made of metal having excellent conductivity on a lower metal layer.

In the embodiment, a chromium (Cr) layer is formed as the lower metal layer and followed by a gold (Au) layer formed as the electrode layer, and then the electrode having a shape shown in FIG. 1 is formed by a method such as photolithography.

In this case, the lower layer and the electrode layer not shown are formed by sputtering or vapor-deposition. However, in a batch processing for forming a plurality of piezoelectric resonator elements from quarts wafers, the layers are preferably formed by vapor-deposition.

In addition, as shown in FIG. 3, the base 51 is preferably provided with indented parts that are formed by partially reducing the dimension in the width direction of the base 51, or with cut parts 71 and 72, at the both side edges sufficiently apart from the end part provided with the resonating arms.

Accordingly, when the resonating arms 35 and 36 perform a flexural vibration, the vibration is leaked to the base 51 and suppressed from being propagated to the supporting arms 61 and 62, thereby keeping a crystal impedance (CI) value low.

Here, in a case of where the strength can allow, a through-hole not shown is formed near the center of the base 51 to concentrate stress around the circumference of the through-hole. Accordingly, the vibration can be prevented from being propagated to the supporting arms 61 and 62, thereby keeping the CI value low.

As shown in FIG. 3, a portion between the cut parts 71 and 72 is a joining part 73. The joining part 73 is integrally connected to a connecting part 74 serving as an extended part extending in directions of both sides on the other end of the base 51. That is, the portion (connecting part 74) extending in the width direction of the base 51 at the outermost is a portion to join a pair of the supporting arms 61 and 62 that are in parallel to each other and functions as the connecting part.

Next, a structure of the supporting arms will be described.

Since the supporting arms 61 and 62 have an identical shape, the supporting arm 61 will be explained referring to FIG. 3. The length dimension u is required to be from 60 to 80% of the whole length a of the piezoelectric resonator element 32 in order to achieve a stable supporting structure.

Further, outside corner parts 61a and 62a of the supporting arms 61 and 62 are chamfered in an R-shaped manner, which is convexed toward outside or concaved toward inside, preventing damages such as cracking to the supporting arms 61 and 62.

As the portion of the supporting arms bonding to the electrode parts 31-1 and 31-2 formed on the second substrate 55 of the package 57, for example, for the supporting arm 61 of one side, only one bonding portion corresponding to the gravity center position G of the length dimension of the piezoelectric resonator element 32 can be selected. However, as shown in FIG. 1, it is preferable that the electrode portions 31-1 and 31-2 be set and bonded by selecting two points being apart at equal distance from the gravity center position G. In this way, the bonding structure is further enhanced and becomes stable.

When one supporting arm is bonded at one point, it is preferable for achieving a sufficient bonding strength that the length of a region for applying an adhesive be maintained so as to be 25% or more of the whole length a of the piezoelectric resonator element 32.

In a case of providing two bonding points (four points in total on both of the supporting arms) as described in the embodiment, it is preferable for achieving a sufficient bonding strength that the distance between the bonding portions be allowed to be 25% or more of the whole length a of the piezoelectric resonator element 32.

Here, at least one set of the electrode parts 31-1 and 31-2 among the electrode parts 31-1 and 31-2 is connected to the mounting terminal 41 on the backside of the package via conductive through holes or the like. The package 57 is hermetically sealed by bonding the lid 40 that is made of glass and transparent with the sealing member 58 after housing the piezoelectric resonator element 32.

A structure may be employed in which the lid 40, which is, for example, a metal plate such as kovar, not a transparent material, is bonded by a seam sealing.

Here, in the embodiment, the other end part 53, from which the supporting arms 61 and 62 extend, of the base 51 is located to keep the distance BL (the length L2 of the base and the length of the cut part) sufficiently apart from a footing part 52 of the resonating arms 35 and 36.

The dimension of the distance BL is preferably more than an arm width dimension W of the resonating arms 35 and 36.

Namely, when the resonating arms 35 and 36 of a tuning fork type resonator element perform a flexural vibration, the area in which the vibration leakage is propagated toward the base 51 has a correlation with the arm width dimension W of the resonating arms 35 and 36. The inventor focuses attention to this point, having knowledge that the position serving as the base end of the supporting arms 61 and 62 should be disposed at an adequate position.

Therefore, in the embodiment, the part 53, which serves as the base end of the supporting arms 61 and 62 has a structure that can further ensure that propagation of the vibration leakage from the resonating arms 35 and 36 to the supporting arms 61 and 62 is suppressed by choosing a position that exceeds the dimension corresponding to the size of the arm width dimension W of the resonating arms from the footing part 52 of the resonating arms severing as an origin. Therefore, in order to obtain advantageous effects of the supporting arms, which will be described later, with suppressing CI value, it is preferable that the position of the part 53 be apart from the footing part 52 (i.e. one end part of the base 51) of the resonating arms 35 and 36 by the distance BL.

According to the same reason, it is preferable that the positions at which the cut parts 71 and 72 are formed be apart from the footing part 52 of the resonating arms 35 and 36 by the distance that is more than the size of the arm width dimension W of the resonating arms 35 and 36. Therefore, the cut parts 71 and 72 are formed at the positions including a part where the supporting arms 61 and 62 are integrally connected to the base 51, and being more adjacent to the resonating arms from the part.

Here, since the supporting arms 61 and 62 are uninvolved in the vibration, no specific conditions are required to the arm width dimension W. However, it is preferable that the width W be larger than that of the resonating arm in order to assure a supporting structure.

Consequently, in the embodiment, a width BW of the piezoelectric resonator element 32 can be achieved to be 500 μm by being composed of the followings: the resonating arms having the arm width dimension W of approximately 50 μm; a distance MW between the resonating arms is approximately 80 μm; and the supporting arms 61 and 62 having the width f of approximately 100 μm. The piezoelectric resonator element 32 has the width BW, which is nearly equal to the width of the piezoelectric resonator element 1 in FIG. 14, and shorter in length, being fully housed in the package having the same size as that of the conventional one. In the embodiment, the following advantageous effects are obtained while such miniaturization is achieved.

In the piezoelectric resonator element 32 in FIG. 1, the supporting arms 61 and 62 are bonded to the package 57 with the conductive adhesives 43. Therefore, the stress change produced at the bonding portion due to the change of surrounding temperature or a drop shock or the like can hardly affect the resonating arms 35 and 36 due to the crooked distance from the bonding portion of the supporting arms 61 and 62 to the other end part 53 of the base 51, and even further through the distance of the length of the base 51, which is more than the distance BL, resulting in showing particularly favorable temperature characteristics.

In contrast, vibration leakage from the resonating arms 35 and 36 performing the flexural vibration is hardly propagated, since the predetermined length of the base 51 which is more than the distance BL is given before the vibration leakage reaches to the supporting arms 61 and 62 through the base 51.

If the length of the base 51 is extremely short, it can be considered that a situation in which a leaked component of the flexural vibration spreads over the supporting arms 61 and 62 and causes difficulty in control. However, in the embodiment, such situation is thoroughly avoided.

In addition to the advantageous effects, the supporting arms 61 and 62 are extended from the other end part 53 of the base 51 in the width direction, and extended in the same direction of the resonating arms 35 and 36 at outer side of the resonating arms 35 and 36 as illustrated, making the whole size compact.

Further, in the embodiment, distal parts of the supporting arms 61 and 62 are formed so as to be closer to the base 51 than the distal parts of the resonating arms 35 and 36 as shown in FIG. 1. On this point, the size of the piezoelectric resonator element 32 also can be made compact.

Moreover, as compared with the structure of FIG. 1, the followings can easily be understood. In FIG. 14, conductive adhesives 7 and 8 are applied to lead-out electrodes 5 and 6, both of which are closely located. Because of this structure, a bonding step has not been easy to carry out since the adhesives need to be applied to an extremely narrow area (of the package) so as not to contact to each other for avoiding a short circuit, and even after bonding, the step needs to be proceeded not to flow out the adhesives before curing it as they may cause a short circuit.

In contrast, in the piezoelectric resonator element 32 in FIG. 1, the conductive adhesives 43 are merely applied to the electrode parts 31-1 and 31-2 that are respectively located at an approximately intermediate position of the supporting arms 61 and 62, both of which are spaced apart across the width direction of the package 57. This causes seldom difficulties described as above, and also no concerns for a short circuit.

Further, in the piezoelectric resonator element 32 in FIG. 3, the length of the resonating arms is indicated as L1 while the length of the base 51 is indicated as L2 (the distance BL minus the length of the cut part).

A width L3 of the connecting part that is integrally connected between the supporting arm 62 and the joining part 73 is preferably from 60 μm to 100 μm. That is, it is difficult to manufacture a piezoelectric resonator element whose width L3 is less than 60 μm. If the width L3 exceeds 100 μm, not only hindering miniaturization of the piezoelectric resonator element, but also causing difficulty in making a ratio L3/h from 20% to 40% where h is a length dimension from the one end of the base 51 provided with the resonating arms 35 an 36 up to the other end opposite to the resonating arms 35 and 36 of the piezoelectric resonator element, and L3 is a width dimension of the connecting part.

The width dimension L3 in FIG. 3 is a width dimension of a reduced-width portion that is more constricted than a width dimension L3-1 that is an original width dimension of the connecting part 74, which is a slightly wide.

This is because of the following reasons.

According to a study by the inventor et al., when the supporting arm 62 serving as the bonding portion is joined to the package or the like, an effect of the adhesives used thereto, in particular, an effect by remaining stress at a low temperature due to a temperature characteristic at a low temperature test arises. It is considered that the effect is propagated along a pass from the base 51 to the resonating arms through the connecting part 74 and the joining part 73. This remaining stress adversely affects the flexural vibration of the resonating arms 35 and 36. To prevent it, a part on which stress can concentrate can be formed somewhere in the pass.

However, according to various tryouts, although an effect to a certain extent can be expected by forming a cutout or the like in a part other than a region where the supporting arms 61 and 62 are joined, rigidity of a whole of the supporting arms themselves for supporting is reduced and an effect of vibration leakage from the resonating arms arises. Therefore, the result is not always satisfactory.

Alternatively, a quite favorable effect can be expected by deepening the cut parts 71 and 72 and reducing the joining part 73 in size as it will be described later. However, a result obtained by merely reducing a width dimension r of the joining part 73 was not satisfactory since it became too close to the resonating arms.

Therefore, it is found that where h is the length dimension from the one end of the base 51 provided with the resonating arms 35 and 36 up to the other end opposite to the resonating arms 35 and 36 of the piezoelectric resonator element, and L3 is the width dimension of the connecting part, the ratio L3/h should be 40% or less, resulting in a considerably favorable effect as it will be described later.

In the base 51, the width dimension L3 is constricted more than the width dimension L3-1 that is the original width dimension of the connecting part 74, which is slightly wide. The width dimension of the reduced-width portion is L3 as described above, however, when the reduced-width portion is not formed according to convenience of the manufacturing step, L3 should be equal to L3-1.

Next, the preferable detailed structure of the piezoelectric resonator element 32 of the embodiment will be explained referring to FIGS. 3 and 4.

Since the resonating arms 35 and 36 of the piezoelectric resonator element 32 shown in FIG. 3 have an identical shape, the resonating arm 36 will be explained. The resonating arm width is the widest at abase end part T of the base 51 from which each of the resonating arms is extended. A first reduced-width portion TL, which drastically reduces the width between the positions of T to U, is formed. The position of T is the footing part of the resonating arm 36. The position U is apart from the position T toward the distal side of the resonating arm 36 with a little distance. A second reduced-width portion, which gradually and continuously decreases the width from the position of U to the position of P, namely, across the distance of CL on the resonating arm. The position of U is the end of the first reduced-width portion TL. The position of P is apart from the position of U further toward the distal side of the resonating arm 36.

Accordingly, the resonating arm 36 has high rigidity around the footing part close to the base by providing the first reduced-width portion TL. The resonating arm 36 also has rigidity continuously decreased by forming the second reduced-width portion CL, which is formed from the point U serving as the end of the first reduced-width portion to the top. The position of P is a changing point P at which the arm width is changed. Further, it is a constricted position of the resonating arm 36 from the shape. Thus, it also can be expressed as a constricted position P. In the resonating arm 36, the arm width extends from the changing point P to the distal side with the same width, or preferably, with the width gradually and slightly widened as shown in the figure.

Here, the longer the long grooves 33 and 34 in FIG. 3, more increasing the electric field efficiency of the material forming the resonating arms 35 and 36. Here, the longer the long grooves, the lower a CI value of the tuning fork type resonator element, at least j/L1 is up to approximately 0.7, where L1 is the whole length of the resonating arm 36 and j (length of the long grooves) is the length of the long grooves 33 and 34 from the base 51. Therefore, j/L1 is preferably from 0.5 to 0.7. In the embodiment, the whole length L1 of the resonating arm 36 is, for example, approximately 1250 μm in FIG. 3.

In addition, when the length of the long groove is adequately elongated to thoroughly suppress the CI value, a problem arising next is a CI value ratio (CI value of harmonic wave/CI value of fundamental wave) of the piezoelectric resonator element 32.

Namely, when the CI value of a fundamental wave is reduced, the CI value of the harmonic wave is simultaneously suppressed. Then, if the CI value of a harmonic wave is smaller than the CI value of the fundamental wave, oscillation with the harmonic wave easily occurs.

Therefore, in addition to elongating the long groove to reduce the CI value, the changing point P where the arm width is changed from being reduced to being enlarged is further provided closely to the distal part of the resonating arm. This allows the CI value ratio (CI value of harmonic wave/CI value of fundamental wave) to be more increased while reducing the CI value.

Namely, the rigidity of a root part, i.e. in the vicinity of the footing part, of the resonating arm 36 is enhanced by the first reduced-width portion TL. This enhanced rigidity allows the flexural vibration of the resonating arms to be more stable. As a result, the CI value can be suppressed.

Since the second reduced-width portion CL is provided, the rigidity of the resonating arm 36 is gradually lowered from its footing part toward the distal part, to the constricted position P serving as the changing point of the arm width. From the constricted position P to the distal part, the rigidity of the resonating arm 36 is gradually increased because the long groove 34 is not provided, and the width of the resonating arm is gradually widened.

Therefore, it is considered that node of the vibration in the second harmonic wave can be shifted to the position closer to the distal part of the resonating arm 36. As a result, lowering the CI value of the second harmonic wave cannot be provoked while the CI value of the fundamental wave is suppressed even when the CI value of the second harmonic wave is increased by elongating the long groove 34 so as to increase the electric field efficiency. Consequently, the CI value ratio is almost certainly increased by preferably providing the changing point P of the arm width closer to the distal part of the resonating arm from the end part of the long groove as shown in FIG. 3, preventing an oscillation with the harmonic wave.

Moreover, according to researches by the inventor et al., j/L1, an arm width reduction ratio M, and the CI value ratio (CI value the second harmonic wave/CI value of the fundamental wave) corresponding to them are correlated, where L1 is the whole length of the resonating arm, j is the length of the grooves 33 and 34 from the base 51, M is the ratio of the maximum width and the minimum width of the resonating arm 36, and CI value ratio is the ratio of the CI value of the second harmonic wave and the CI value of the fundamental wave.

In addition, it is confirmed that the oscillation with the harmonic wave can be prevented by the CI value ratio that becomes more than one (1) by increasing the arm width reduction ratio M, which is the ratio of the maximum width and the minimum width of the resonating arm 36, so as to be more than 1.06 in a case where j/L1 is 61.5%.

As a result, the piezoelectric resonator element that can control the CI value of the fundamental wave at low value, and does not deteriorate drive characteristics even though it is wholly miniaturized can be provided.

Next, more preferable structure of the piezoelectric resonator element 32 will be explained.

A wafer thickness, i.e. the thickness of a quartz wafer forming a piezoelectric resonator element, shown in FIG. 4 as a dimension x is preferably from 70 μm to 130 μm.

The whole length of the piezoelectric resonator element 32 shown in FIG. 3 as a dimension a is approximately from 1300 μm to 1600 μm. It is preferable for miniaturizing the piezoelectric device that the dimension L1, which is the whole length of the resonating arm, is from 1100 μm to 1400 μm, while a whole width d of the piezoelectric resonator element 32 is from 400 μm to 600 μm. Accordingly, in order to miniaturize the tuning fork part, it is required for ensuring a supporting effect that a width dimension e of the base 51 is from 200 μm to 400 μm, while a width f of the supporting arm is from 30 μm to 100 μm.

A dimension k between the resonating arms 35 and 36 in FIG. 3 is preferably from 50 μm to 100 μm. If the dimension k is less than 50 μm, it is difficult to sufficiently lessen a fin shaped convex part, which is an irregular shaped part due to an anisotropy in etching, in the plus X-axis direction on the side of the resonating arm shown in FIG. 4 with numeral 81 when the outer shape of the piezoelectric resonator element 32 is formed by wet etching a quartz wafer so as to penetrate through the wafer, which will be described later. If the dimension k is 100 μm or more, the flexural vibration of the resonating arms may be unstable.

In addition, both dimensions m1 and m2 are from 3 μm to 15 μm. Each of them is the dimension between the outer edge of the long groove 33 and the outer edge of the resonating arm 35 (the same as in the resonating arm 36) in FIG. 4. When the dimensions m1 and m2 are 15 μm or less, the electric field efficiency is improved, while when the dimensions m1 and m2 are 3 μm or more, it is advantageous to ensure polarization of electrodes.

In the resonating arm 36 in FIG. 3, when the width dimension m of the first reduced-width portion TL is 11 μm or more, it is expected to show a definite effect on suppressing the CI value.

In the resonating arm 36 in FIG. 3, it is preferable that the arm width be increased from the changing point P of the arm width to the distal part by approximately from 0 μm to 20 μm with respect to the width of the changing point P of the arm width, which is the position at which the arm width of the resonating arm 36 is the minimum. When the width is widened over the width described above may cause deterioration in stability of the flexural vibration since the distal part of the resonating arm 36 is overweighted.

Further, the irregular shaped part 81 is formed on one side of the outer side of the resonating arm 35 (the same as in the resonating arm 36) in FIG. 4. The irregular shaped part 81 has a fin shape and is protruded in the plus X-axis direction. This is formed as etching remains due to an etching anisotropy in etching quartz when the piezoelectric resonator element is wet etched for forming its outer shape. In order to achieve the stable flexural vibration of the resonating arm 35, it is preferable that a protruded amount v of the irregular shaped part 81 is reduced within 5 μm by performing the etching in the etching solution containing hydrofluoric acid and ammonium fluoride for 9 to 11 hours.

It is preferable that the width dimension of the long groove that is shown as a dimension g in FIG. 3 be approximately from 60% to 90% with respect to an arm width c of the resonating arm in the region of the resonating arm, in which the long groove is formed. The arm width c varies depending on positions along the longitudinal direction of the resonating arm since the first and second reduced-width portions are formed in the resonating arms 35 and 36. The width g of the long groove is approximately from 60% to 90% with respect to the maximum width of the resonating arm. If the width of the long groove is smaller than the above, the electric field efficiency is lowered, resulting in CI value being increased.

Further, h that indicates the length from the one end of the base 51 provided with the resonating arms 35 and 36 in FIG. 3 up to the other end opposite to the resonating arms 35 and 36 of the piezoelectric resonator element is approximately 30% with respect to the whole length a of the piezoelectric resonator element 32 conventionally. However, in the embodiment, h can be approximately from 15% to 25% by employing the cut part etc., resulting in achieving the miniaturization.

For example, h that indicates the length from the one end of the base 51 provided with the resonating arms 35 and 36 up to the other end opposite to the resonating arms 35 and 36 of the piezoelectric resonator element can be from 150 μm to 300 μm.

Moreover, as shown in FIG. 1, indented parts or the cut parts 71 and 72 are preferably disposed at both side edges of the base 51. Its depth (a dimension q in FIG. 3) can be, for example, approximately 80 μm.

In addition, in the embodiment, a ratio L3/h is nearly 40% or less where h is the length dimension from the one end of the base 51 provided with the resonating arms 35 an 36 up to the other end opposite to the resonating arms 35 and 36 of the piezoelectric resonator element, and L3 is the width dimension of the connecting part 74 where supporting arms 61 and 62 are connected to the base 51 through the joining part 73. In this case, the ratio L3/h mentioned above is preferably 20% or more.

Accordingly, effects to be described later can be provided.

Further, in the embodiment, the distance (dimension p) between the side of the base 51 and the supporting arm 61 or 62 is from 30 μm to 100 μm in order to miniaturize the package dimension.

As shown in FIG. 4, each of the excitation electrodes 37 and 38 of the piezoelectric resonator element 32 is coupled to an alternating current power supply source with a cross wiring. An alternating voltage serving as a driving voltage is applied to each of the resonating arms 35 and 36 from the power supply source.

Accordingly, the resonating arms 35 and 36 are excited so as to vibrate in a phase opposite to each other. In a fundamental mode, i.e. the fundamental wave, the resonating arms 35 and 36 perform the flexural vibration so that their distal sides are moved closer and then apart.

Here, the fundamental wave of the piezoelectric resonator element 32 is, for example, as follows: Q value is 12000; capacitance ratio (C0/C1) is 260; CI value is 57 kΩ; and frequency is 32.768 kHz (“kilo hertz,” hereinafter referred to as kHz).

Also, the second harmonic wave is, for example, as follows: Q value is 28000; capacitance ratio (C0/C1) is 5100; CI value is 77 kΩ; and frequency is 207 kHz.

FIG. 5 is a circuit diagram illustrating an example of an oscillation circuit when a piezoelectric oscillator is structured by using the piezoelectric resonator element 32 of the embodiment.

An oscillation circuit 91 includes an amplifying circuit 92 and a feedback circuit 93.

The amplifying circuit 92 is provided with an amplifier 95 and a feedback resistor 94. The feedback circuit 93 is provided with a drain resistor 96, capacitors 97 and 98, and the piezoelectric resonator element 32.

Here, in FIG. 5, the feedback resistor 94 is, for example, approximately 10 MΩ (mega ohm). The amplifier 95 can employ a CMOS inverter. The drain resistor 96 is, for example, from 200 to 900 kΩ (kilo ohm). Each of the capacitor 97 (drain capacitance) and the capacitor 98 (gate capacitance) is from 10 to 20 pF (pico farad).

The piezoelectric resonator element 32 and the piezoelectric device 30 according to the embodiment are structured as above. Now, characteristic effects will be described.

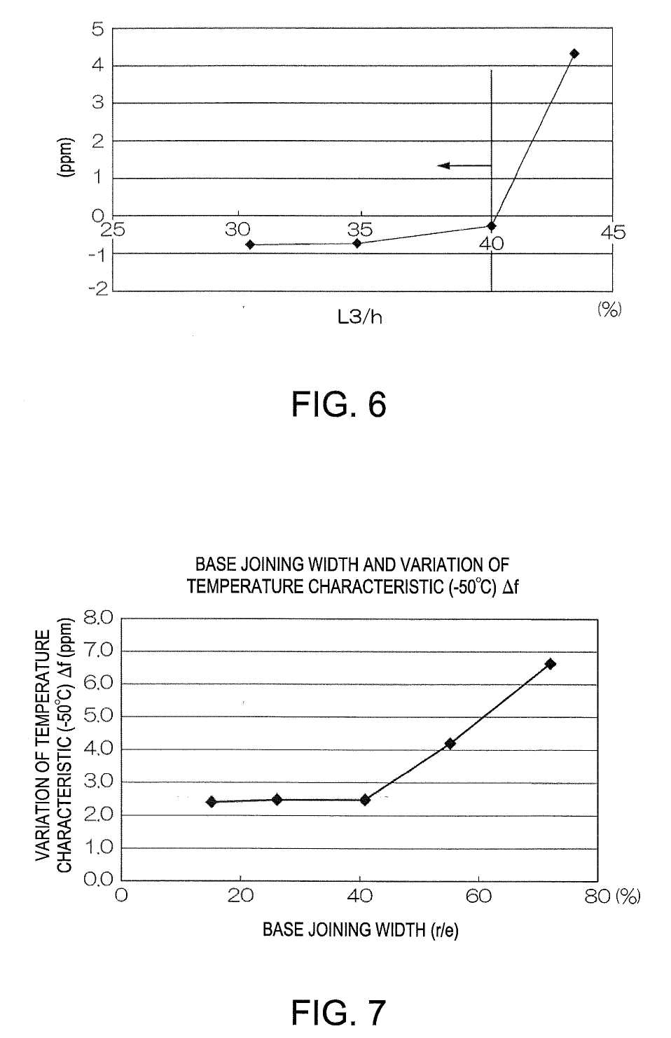

As it has been described, the piezoelectric resonator element 32 according to the embodiment as shown in FIG. 3, the ratio L3/h is nearly 40% or less where h is the length dimension from the one end of the base 51 provided with the resonating arms 35 an 36 up to the other end opposite to the resonating arms 35 and 36 of the piezoelectric resonator element, and L3 is the width dimension of the connecting part 74 where supporting arms 61 and 62 are respectively connected to the base 51 through the joining part 73. As a result, effect shown in FIG. 6 can be expected.

That is, in FIG. 6, a horizontal axis indicates a value of L3/h, while a vertical axis indicates a shift (difference) of frequency with respect to an ideal temperature characteristic at −50° C.

In the figure, frequency shift is extremely small in a region in which L3/h is 40% or less. Further, the frequency shift becomes even smaller in a region in which L3/h is 35% or less. In addition, when it becomes smaller by exceeding a lower limit of L3/h that is about 20%, a side effect such as breakage occurs in an assembly step.

More preferably, a ratio r/e is from 23% to 40% where r is a width dimension of the joining part 73 and e is a width dimension of the base 51 of the piezoelectric resonator element 32 shown in FIG. 3.

When the ratio r/e is less than 23%, it is confirmed that the joining part mentioned above may be split by an impact from outside such as a drop shock.

Therefore, when the ratio is 23% or more, and besides 40% or less, the piezoelectric resonator element in which the resonating arms serving as the excitation part are hard to be affected by the supporting arms including the bonding portion to the package and the like and further without being easily damaged by an impact from outside can be obtained.

The piezoelectric resonator element 32 and the piezoelectric device 30 according to the embodiment are structured as above. Now, characteristic effects will be described.

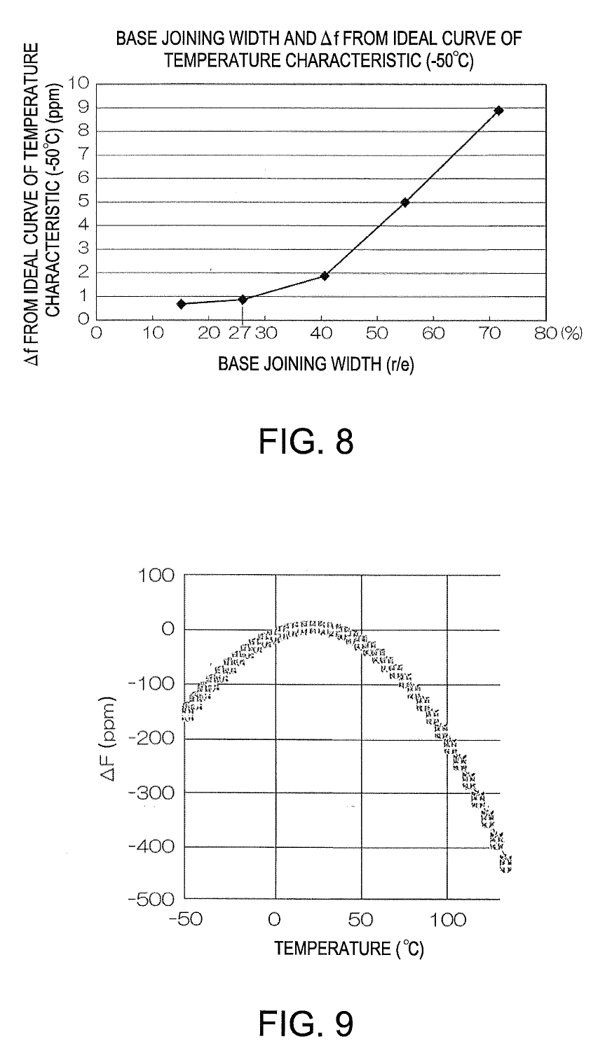

In the piezoelectric resonator element 32 according to the embodiment, results shown in FIGS. 7 and 8 can be expected by making the ratio r/e a predetermined ratio where r is the width dimension of the joining part 73 and e is a width dimension of the base 51 in FIG. 3.

That is, in FIG. 7, a horizontal axis indicates the r/e ratio while a vertical axis indicates a temperature characteristic at −50° C., particularly, variation of frequency. In FIG. 8, a horizontal axis indicates the r/e ratio while a vertical axis indicates a temperature characteristic at −50° C., particularly, a shift of frequency with respect to an ideal temperature characteristic.

Those figures show that either variation of frequency (FIG. 7) or shift of frequency (FIG. 8) can be improved by reducing the width dimension r of the joining part 73 in size.

Particularly, when the ratio r/e is about 40% by gradually reducing the width dimension r of the joining part 73, the variation of frequency is improved up to about 2.5 ppm.

On the other hand, the shift of frequency in FIG. 8 keeps improving gradually after the ratio r/e is further reduced to be over 40%.

However, according to an attempt by the inventor et. al., when the ratio r/e is less than 23%, it is confirmed that the joining part 73 may be split by an impact from outside such as a drop shock in a case where the piezoelectric device is dropped or in similar situations.

Accordingly, when the ratio r/e is from 23% to 40%, in the piezoelectric resonator element 32 and the piezoelectric device 30 housing it, each of the resonating arms 35 and 36 is extremely hard to be affected by the supporting arms 61 and 62 including the bonding portion to the package 57, besides, not easily damaged by an impact from outside.

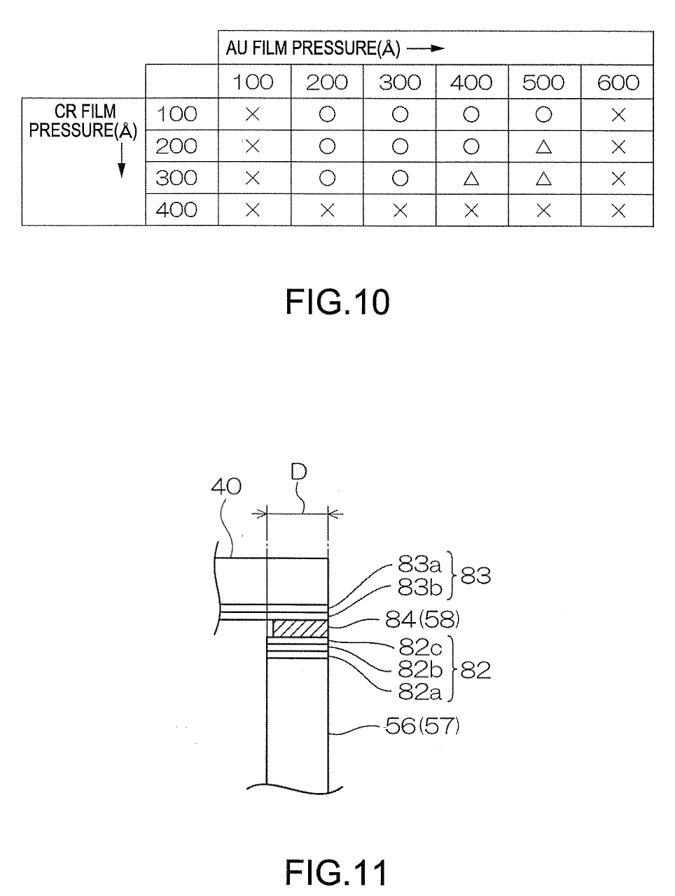

Next, FIG. 9 shows a result of a temperature characteristic test of the piezoelectric resonator element 32 according to the embodiment. By corresponding to this, FIG. 10 shows a relation between each thickness of a chromium layer and a gold layer and frequency distortion (variation of frequency) at a low temperature by being organized using symbols of a circle, a triangle, and a cross. The chromium layer is a lower metal layer forming the excitation electrodes 37 and 38 of the piezoelectric resonator element 32 in FIG. 3 while the gold layer is an electrode layer.

As shown in FIG. 9, the circle shows the best result in which the variation of frequency is extremely small in a low temperature region. The triangle shows a result that is almost good, while the cross shows a result that is not favorable.

That is, when the thickness of the chromium layer serving as the lower layer of an electrode film composing the excitation electrodes 37 and 38 is 300 \acute{Å} or less, and the thickness of the gold layer is 500 \acute{Å} or less, the favorable result that is the triangle or a better result than the triangle described as above can be obtained.

Namely, the chromium layer having the thickness of 300 \acute{Å} or less can prevent Young's modulus of the electrode parts at a low temperature from being too large. Further, the gold layer having the thickness of 500 \acute{Å} or less can prevent cost for forming electrodes from increasing. Accordingly, even when the piezoelectric resonator element 32 is made small, the piezoelectric resonator element having a favorable temperature characteristic can be provided by suppressing the CI value hindering the flexural vibration when a temperature is low and preventing the frequency distortion at a low temperature while serving sufficient conduction performance.

Further, as shown in FIG. 10, when the thickness of the chromium layer serving as the lower layer of the electrode film composing the excitation electrodes 37 and 38 is 200 \acute{Å} or less, the thickness of the gold layer serving as the electrode film is preferably 400 \acute{Å} or less.

That is, when the thickness of the chromium layer is suppressed to be 200 \acute{Å} or less, the thickness of the gold layer is 400 \acute{Å} or less so as to be a sufficient film thickness, preventing frequency distortion at a low temperature even the conduction performance is improved.

Further, as shown in FIG. 10, when the thickness of the chromium layer is 100 \acute{Å} or less, the thickness of the gold layer is preferably 500 \acute{Å} or less.

That is, when the thickness of the chromium layer is suppressed to be 100 \acute{Å} or less, the thickness of the gold layer is 500 \acute{Å} or less so as to be a sufficient film thickness, preventing frequency distortion at a low temperature even the conduction performance is further improved.

[Method for Manufacturing a Piezoelectric Device]

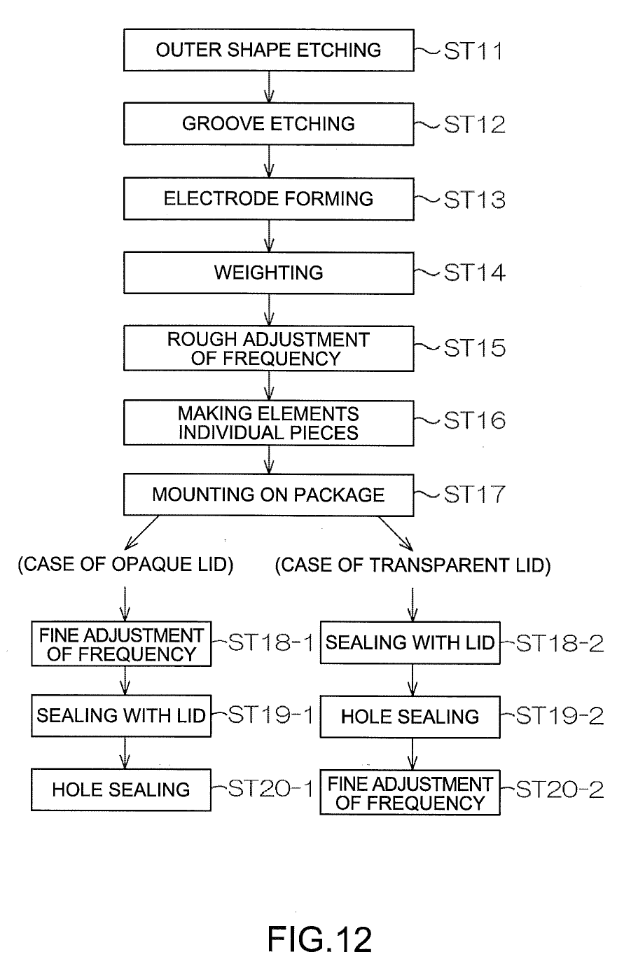

Next, an example of a method for manufacturing the piezoelectric device described above will be explained referring to a flow chart in FIG. 12.

[Method for Manufacturing a Lid and a Package]

The piezoelectric resonator element 32, the package 57, and the lid 40 in the piezoelectric device 30 are individually manufactured.

The lid 40 is prepared as the lid having a suitable size for sealing the package 57 by cutting, for example, a glass plate having a given size, for example, a sheet glass of borosilicate glass.

The package 57 is formed, as described above, by multilayering a plurality of substrates made of aluminum-oxide ceramic green sheets, followed by firing. In the forming, each of the plurality of substrates is provided with a given hole inside therein so as to form the inner space S as predetermined when they are laminated.

[Method for Manufacturing a Piezoelectric Resonator Element]

First, a piezoelectric substrate is prepared. Then, a given number of piezoelectric resonator elements are simultaneously formed from one piezoelectric substrate by etching their outer shapes (outer shape etching).

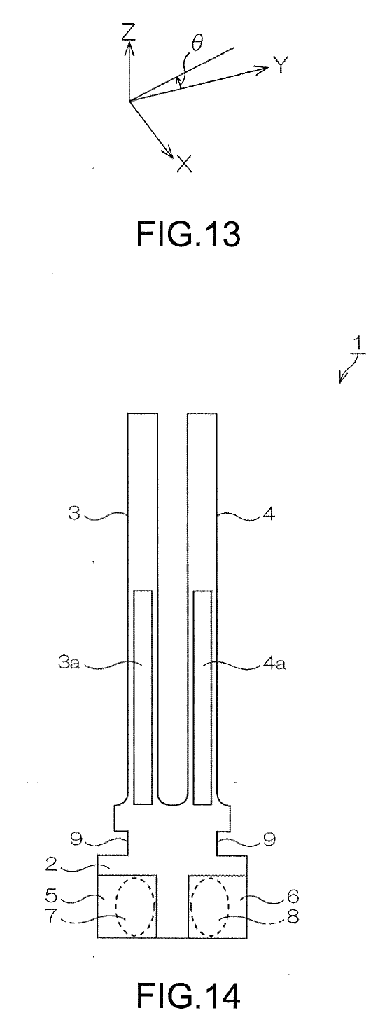

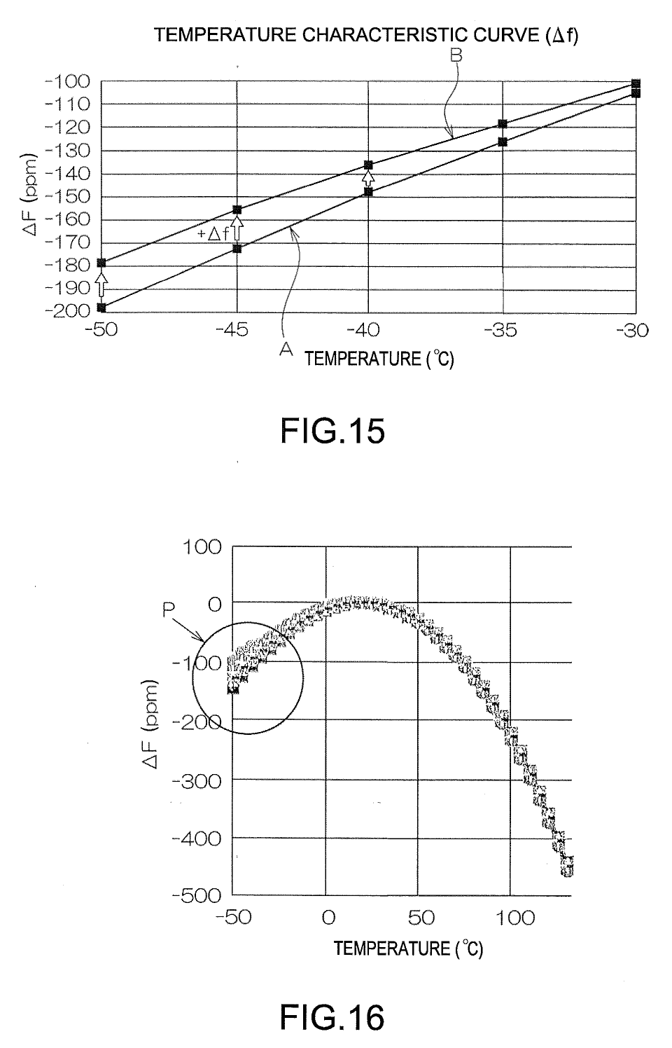

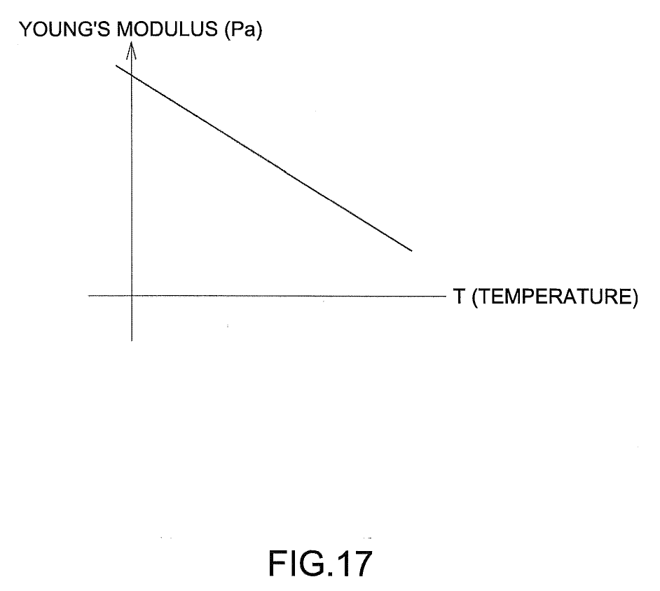

Here, for example, a quartz wafer having a size capable for dividing it into a several number or a many number of the piezoelectric resonator elements 32 is used from piezoelectric materials as the piezoelectric substrate. The piezoelectric substrate is cut from the piezoelectric material, for example, a single crystal of quartz, so that the X axis is electrical axis, the Y-axis is mechanical axis, and the Z-axis is optical axis, which are shown in FIG. 1 or 4, because the piezoelectric substrate forms the piezoelectric resonator element 32 in FIG. 3 as the manufacturing steps proceed. The piezoelectric resonator element 32 in FIG. 1 is also manufactured in the same manner. A quartz Z plate is cut by being rotated within a range of zero (0) to five (5) degrees in clock wise about the Z-axis (θ in FIG. 13) in the orthogonal coordinate system composed of the X, Y, and Z-axes when cutting it from the single crystal of quartz. Then, the quartz Z plate is cut and polished to be a given thickness.

In the outer shape etching, the piezoelectric substrate exposed as an outside part from the outer shape of the piezoelectric resonator element is subjected to the etching of the outer shape of the piezoelectric resonator element by using, for example, a hydrofluoric acid solution as an etchant with a mask such as a corrosion resistant film (not shown). As the corrosion resistant film, for example, a metal film such as gold that is vapor deposited on chromium serving as a lower layer, or the like can be used. The etching process varies depending on the concentration, kind, temperature, and so forth of the hydrofluoric acid solution.

Here, the wet etching in the outer shape etching shows the following etching anisotropy to the mechanical axis X, electrical axis Y, and optical axis Z shown in FIG. 3 as the etching proceeds.

Namely, an etching rate in X-Y plain of the piezoelectric resonator element 32 is follows: in the plus X direction, the progression of etching is fast in the plain in the direction of 120 degrees with respect to the X-axis and in the plain in the direction of −120 degrees with respect to the X-axis; and, in the minus X direction, the progression of etching is slow in the plain in the direction of 30 degrees with respect to the X-axis and in the inner surface in the direction of −30 degrees with respect to the X-axis.

Likewise, the progression of etching speed in the Y direction is fast in the plus 30 and −30 degrees. In the plus Y direction, the progression of etching speed is slow in the plus 120 and −120 degrees directions with respect to the Y-axis.

Due to the anisotropy in etching progression as above, the irregular shaped part protruded as a fin shape is formed on the outer side of each of the resonating arms of the piezoelectric resonator element 32 as indicated as numeral 81 in FIG. 4.

However, in the embodiment, the protruded amount v of the irregular shaped part 81 explained in FIG. 4 can be extremely lessen within 5 μm by etching for sufficient time, i.e. from 9 to 11 hours, using hydrofluoric acid and ammonium fluoride as the etchant (ST11).

In this step, the outer shape of the piezoelectric resonator element 32 including the cut parts 71 and 72 is simultaneously formed. When the step is completed, many of the piezoelectric resonator elements 32, each of which is connected to the quartz wafer at the vicinity of the base 51 with a slim connecting part, are achieved as their outer shapes are completed.

[Half Etching Step for Forming Groove]

Next, the resist (not shown) for forming a groove remains as a corrosion resistant film at the part to which the groove is not formed so as to leave both wall parts sandwiching each long groove as shown in FIG. 4. Then, the front and back sides of each of the resonating arms 35 and 36 are wet etched with the same etching condition of the outer shape etching so as to form the bottom corresponding to each long groove (ST12).

Here, with reference to FIG. 4, the depth of the groove indicated by a symbol t is approximately from 30% to 45% with respect to the whole thickness x. If t is 30% or less of the whole thickness x, there can be a case where the electric field efficiency cannot sufficiently be improved. If it is 45% or more, there can be a case where a flexural vibration is adversely affected or strength is insufficient due to the insufficient rigidity.

Here, either of the outer shape etching and the groove etching, or both of them can be performed by dry etching. In this case, for example, a metal mask is disposed in each time on the piezoelectric substrate (quartz wafer) so as to cover the outer shape of the piezoelectric resonator element 32, or a region corresponding to the long groove after forming the outer shape. The piezoelectric substrate with the mask is, for example, put into a chamber (not shown), and then an etchant gas is supplied at a given degree of vacuum in the chamber so as to produce etching plasma. As a result, dry etching can be performed. Namely, for example, a freon gas cylinder and an oxygen gas cylinder are connected to a vacuum chamber (not shown), and further an exhausting pipe is provided to the vacuum chamber so as to vacuum the chamber to be at a given degree of vacuum.

When inside the vacuum chamber is vacuum exhausted to be at a given degree of vacuum, and freon gas and oxygen gas are supplied and charged to reach a given pressure of the mixed gas of the two, a direct-current voltage is applied to generate plasma. Then, the mixed gas containing ionized particles hits the piezoelectric material exposed from the metal mask. The bombardment mechanically chips away and scatters the piezoelectric material. As a result, etching proceeds.

[Electrode Forming]

Next, a metal serving as the electrode, for example, gold is deposited on the entire surface by vapor deposition or sputtering, etc. Then, the electrode for driving shown in FIG. 1 is formed by photolithography using the resist exposing the part on which the electrode is not formed (ST13).

Subsequently, weighted electrodes (metal films) 21 are formed on the distal part of each of the resonating arms 35 and 36 by sputtering or vapor deposition (ST14). The weighted electrodes 21 are not used for driving the piezoelectric resonator element 32 with applying a voltage, but are utilized for a frequency adjustment described later.

Next, frequency is roughly adjusted on the wafer (ST15). The rough adjustment is the frequency adjustment by a mass reduction in which a part of the weighted electrodes 21 are partially evaporated by irradiation of an energy beam such as laser light.

Subsequently, the slim connecting part connected to the wafer is broken off so that an individual piece forming the piezoelectric resonator element 32 is provided (ST16).

Then, as described in FIG. 1, the conductive adhesives 43 are respectively applied on the electrodes 31-1 and 31-2 of the package 57. On the conductive adhesives 43, the supporting arms 61 and 62 are placed. By heating and curing the adhesives, the piezoelectric resonator element 32 is bonded to the package 57 (ST17).

Here, the conductive adhesives 43 are, for example, ones that are composed of a binder utilizing synthetic resins or the like, and conductive particles such as silver particles or the like that are mixed into the binder, and can simultaneously perform a mechanical connection and an electrical connection.

Next, the lid is bonded.

When the package 57 is sealed with the lid 40, which is transparent, the lid 40 is bonded to the package 57 after bonding the piezoelectric resonator element 32 in the step of ST17 (ST18-2).

In this case, for example, a heating step is performed in which the lid 40 is bonded to the package 57 by heating a low melting point glass or the like. At this time, a gas is produced from the low melting point glass and the conductive adhesive and the like.

Therefore, the gas is exhausted from the through hole 27 described in FIG. 2 by heating (degassing). Then, a metal ball or pellet preferably made of gold tin or the like is disposed to a stepped part 29 in vacuum, being melt by an irradiation of laser light, or the like. As a result, the sealing member 28 (metal filler) in FIG. 2 hermetically seals the through hole 27 (ST19-2).

Then, as shown in FIG. 2, a distal side of the weighted electrode 21 of the resonating arm 35 and/or 36 of the piezoelectric resonator element 32 is irradiated by laser light from outside so as to transmit through the lid 40 that is transparent and made of glass or the like, performing the frequency adjustment serving as a fine tuning by the mass reduction (ST20-2). After required inspections, the piezoelectric device 30 is completed.

Alternatively, it is more preferable that one made of a metal be used as the lid 40 to bond as shown in FIG. 11.

Before bonding the lid, the piezoelectric resonator element 32 is energized while being bonded to the package and a part of the weighted electrodes 21 of the resonating arms 35 and 36 are partially evaporated by irradiation of an energy beam such as laser light so as to finely adjust the frequency by mass reduction. (ST18-1)

Next, sealing with the lid is performed.

FIG. 11 is a partial sectional view explaining a bonding condition of the lid 40.

In this case, Kovar that is an alloy of iron and cobalt is preferably used as the lid 40.

On an upper end of the package 57, a metallized portion 82 is formed in advance. The metallized portion 82 formed on the package includes each layer of tungsten (W) 82a, nickel (Ni) 82b, and gold (Au) 82c formed sequentially from bottom to top in this order, for example. Alternatively, a layer structure of molybdenum (Mo) 82a, nickel (Ni) 82b, and gold (Au) 82c is also possible.

On the other hand, the lid 40 made of Kovar includes a plated layer 83 formed on at least a bonding surface thereof. The plated layer 83 is a gold (Au) layer 83b that is plated on a surface of the nickel (Ni) layer 83a. That is, gold is exposed on the bonding surface of both the package and the lid. As the sealing member 58, a brazing member 84 made of a gold (Au)-germanium (Ge) alloy is used.

That is, the brazing material 84 made of a gold germanium is melted by heat application in a heat chamber or the like to be bonded (ST19-1).

Here, a bonding step for the lid 40 as above generates heat, and then, a gas is generated from the conductive adhesive or the like, or due to vaporization of a liquid component on an inner surface of the package.

Therefore, as it is similar to ST19-2, for example, a gas generated during the bonding step of the lid as above can be exhausted (degassed) from the through hole 27 described in FIG. 2 by heat application in a vacuum chamber or the like, for example. Then, the metal ball or pellet preferably made of a gold-germanium (Au—Ge) alloy is disposed to the stepped part 29 in vacuum, being melt by an irradiation of laser light, or the like. As a result, the sealing member 28 (metal filler) in FIG. 2 hermetically seals the through hole 27 (ST20-1).

After required inspections, the piezoelectric device 30 is completed.

Consequently, when the lid 40 made of metal is used, by using the brazing material made of a gold-germanium alloy, bonding strength is sufficiently obtained even a size of a bonding allowance is limited compared to a case where the lid made of glass is bonded with the brazing material that is a low-melting glass. Particularly, in degassing using the through hole 27 serving as a sealing hole, excellent airtightness can be achieved without affecting bonding of the lid 40 even when heat is applied thoroughly. Further, when passing through a reflow oven in a mounting step of the piezoelectric device 30, the brazing material is not re-melted, providing excellent bonding performance.

It should be understood that the invention is not limited to the above-described embodiments. The structures of the embodiment can be appropriately combined or omitted, and an additional structure not shown can also be combined therewith.

In addition, the invention can be applied to not only the one in which the piezoelectric resonator element is housed in a box shaped package, but also to the one in which the piezoelectric resonator element is housed in a cylindrical package, the one in which the piezoelectric resonator element functions as a gyro sensor, and further to any piezoelectric devices utilizing a piezoelectric resonator element regardless the name of the piezoelectric resonator element, piezoelectric oscillator, and the like. Moreover, a pair of resonating arms is formed in the piezoelectric resonator element 32. However, the number of resonating arms is not limited to this, but can be three or four or more.

The entire disclosure of Japanese Patent Application Nos: 2006-223318, filed Aug. 18, 2006 and 2006-223319, filed Aug. 18, 2006 and 2006-223320, filed Aug. 18, 2006 are expressly incorporated by reference herein.

What is claimed is:

1. A piezoelectric resonator element, comprising:
a base in a predetermined length, the base being made of a piezoelectric material;
a plurality of resonating arms extending from a first end of the base;
a joining part connected to a second end apart from the first end of the base by a predetermined distance;
a connecting part connected to the joining part and extending in a width direction of the piezoelectric resonator element; and
a supporting arm connected to the connecting part and extending in a same direction as the resonating arm at an outer side of the plurality of resonating arms, wherein a ratio L3/h is 40% or less where h is a length dimension from the first end of the base to the second end opposite to the resonating arms of the piezoelectric resonator element, and L3 is a width dimension of the connecting part connecting the supporting arm to the base through the joining part.

2. The piezoelectric resonator element according to claim 1, wherein the ratio L3/h is from 20% to 40% inclusive where h is the length dimension from the first end of the base to the second end opposite to the resonating arms of the piezoelectric resonator element and L3 is the width dimension of the connecting part.

3. A piezoelectric resonator element, comprising:
a base in a predetermined length, the base being made of a piezoelectric material;
a plurality of resonating arms extending from a first end of the base;
a joining part connected to a second end apart from the first end of the base by a predetermined distance;
a connecting part connected to the joining part and extending in a width direction of the piezoelectric resonator element; and
a supporting arm connected to the connecting part and extending in a same direction as the plurality of resonating arms at an outer side of the resonating arms, wherein a ratio r/e is 40% or less where r is a width of the joining part and e is a width of the base.

4. The piezoelectric resonator element according to claim 3, wherein the ratio r/e is from 23% to 40% inclusive where r is the width of the joining part and e is the width of the base.

5. A piezoelectric resonator element, comprising:
a base in a predetermined length, the base being made of a piezoelectric material;
a plurality of resonating arms extending from a first end of the base, the plurality of resonating arms including an excitation electrode serving as a driving electrode to which a driving voltage is applied formed thereon, the excitation electrode, including:
a chromium layer serving as a lower layer and having a thickness of 300 \acute{Å} or less; and
a gold layer serving as an electrode layer and having a thickness of 500 \acute{Å} or less.

6. The piezoelectric resonator element according to claim 5, further comprising:
a joining part connected to a second end apart from the first end of the base by a predetermined distance;
a connecting part connected to the joining part and extending in a width direction of the piezoelectric resonator element; and
a supporting arm connected to the connecting part and extending in a same direction as the plurality of resonating arms at an outer side of the resonating arms.

7. The piezoelectric resonator element according to claim 1, wherein the connecting part includes a reduced-width portion in which a width of the connecting part is constricted, and the width dimension L3 of the connecting part is a width dimension of the reduced-width portion.

8. A piezoelectric device, comprising:
a piezoelectric resonator element, including:
a base in a predetermined length, the base being made of a piezoelectric material;
a plurality of resonating arms extending from a first end of the base,
a joining part connected to a second end apart from the first end of the base by a predetermined distance;
a connecting part connected to the joining part and extending in a width direction of the piezoelectric resonator element; and
a supporting arm connected to the connecting part and extending in a same direction as the plurality of resonating arms at an outer side of the resonating arms, wherein a ratio L3/h is 40% or less where h is a length dimension from the first end of the base to the second end opposite to the resonating arms of the piezoelectric resonator element and L3 is a width dimension of the connecting part connecting the supporting arm to the base through the joining part; and
a package housing the piezoelectric resonator element.

9. A piezoelectric device, comprising:
a piezoelectric resonator element, including:
a base in a predetermined length, the base being made of a piezoelectric material;
a plurality of resonating arms extending from a first end of the base,
a joining part connected to a second end apart from the first end of the base by a predetermined distance;
a connecting part connected to the joining part and extending in a width direction of the piezoelectric resonator element; and
a supporting arm connected to the connecting part and extending in a same direction as the plurality of resonating arms at an outer side of the resonating arms, wherein a ratio r/e is 40% or less where r is a width of the joining part and e is a width of the base; and
a package housing the piezoelectric resonator element.

10. A piezoelectric device, comprising:
a piezoelectric resonator element, including:
a base in a predetermined length, the base being made of a piezoelectric material;
a plurality of resonating arms extending from a first end of the base, the plurality of resonating arms including an excitation electrode serving as a driving electrode to which a driving voltage is applied formed thereon, the excitation electrode, including:
a chromium layer serving as a lower layer and having a thickness of 300 \acute{Å} or less; and
a gold layer serving as an electrode layer and having a thickness of 500 \acute{Å} or less; and
a package housing the piezoelectric resonator element.

11. The piezoelectric device according to claim 8, wherein the package includes:
a body made of ceramics in a box shape, the body having a through hole communicated with outside and to be sealed;
a lid made of a metal; and
a brazing material made of a gold-germanium alloy for sealing the lid and the body.
